(19) United States
(12) Patent Application Publication
(10) Pub. No.: US 2025/0212533 A1
(43) Pub. Date: Jun. 26, 2025

(54) SEMICONDUCTOR DEVICE

(71) Applicant: KABUSHIKI KAISHA TOSHIBA, Tokyo (JP)

(72) Inventor: Koichi KOKUBUN, Yokohama Kanagawa (JP)

(73) Assignee: KABUSHIKI KAISHA TOSHIBA, Tokyo (JP)

(21) Appl. No.: 19/001,024

(22) Filed: Dec. 24, 2024

Related U.S. Application Data
(62) Division of application No. 17/399,358, filed on Aug. 11, 2021, now abandoned.

(30) Foreign Application Priority Data
Mar. 2, 2021 (JP) 2021-032538

(51) Int. Cl. H10F 30/225; H10F 39/10; H10F 77/00

(52) U.S. Cl. CPC H10F 30/225; H10F 39/107; H10F 77/959

(57) ABSTRACT

An optical detection portion includes a substrate of a first conductivity type, a semiconductor layer of the first conductivity type provided on the substrate, a first conductivity-type layer provided in the semiconductor layer, and a second conductivity-type layer provided on the first conductivity-type layer. The circuit portion includes a first well of a second conductivity type provided in the semiconductor layer, a second well of the first conductivity type provided in the first well, a first drain layer provided in the second well, a first source layer provided in the second well, a second drain layer provided in the first well, and a second source layer.

### CROSS-REFERENCE TO RELATED APPLICATION

This application is a divisional of U.S. application Ser. No. 17/399,358, filed Aug. 11, 2021, which is based upon and claims the benefit of priority from Japanese Patent Application No. 2021-032538, filed on Mar. 2, 2021; the entire contents of both of which are incorporated herein by reference.

### FIELD

Embodiments described herein relate generally to a semiconductor device.

### BACKGROUND

A silicon photomultiplier (SiPM) is a device that includes an avalanche photodiode array driven in a region called the Geiger mode and that can perform photon counting. A device in which SiPM and a complementary metal-oxide-semiconductor (CMOS) circuit are mounted together has been proposed.

### BRIEF DESCRIPTION OF THE DRAWINGS

FIG. 1 is a schematic cross-sectional view of a semiconductor device of the embodiment;

FIG. 2 is an equivalent circuit diagram of an optical detection portion of the semiconductor device of the embodiment;

FIG. 3 is a schematic plan view of a semiconductor layer of a circuit portion of the semiconductor device of the embodiment; and

FIG. 4 is a schematic cross-sectional view of a semiconductor device of another embodiment.

### DETAILED DESCRIPTION

According to one embodiment, a semiconductor device includes an optical detection portion; and a circuit portion processing an electric signal output by the optical detection portion. The optical detection portion includes a substrate of a first conductivity type, a semiconductor layer of the first conductivity type provided on the substrate and having a lower first conductivity-type impurity concentration than the substrate, a back electrode provided on a back surface of the substrate, a first conductivity-type layer provided in the semiconductor layer, a second conductivity-type layer provided on the first conductivity-type layer and in contact with the first conductivity-type layer, and a surface electrode electrically connected to the second conductivity-type layer. The circuit portion includes a first well of a second conductivity type provided in the semiconductor layer, a second well of the first conductivity type provided in the first well, a first drain layer of the second conductivity type provided in the second well, a first source layer of the second conductivity type provided in the second well, a first gate insulating film provided on a surface of the second well between the first drain layer and the first source layer, a first gate electrode provided on the first gate insulating film, a second drain layer of the first conductivity type provided in the first well, a second source layer of the first conductivity type provided in the first well, a second gate insulating film provided on a surface of the first well between the second drain layer and the second source layer, and a second gate electrode provided on the second gate insulating film.

Embodiments will now be described with reference to the drawings. The same components in the drawings are marked with the same reference numerals. In the following embodiments, a first conductivity type is described as a P-type, and a second conductivity type is described as an N-type. However, the first conductivity type may be the N-type, and the second conductivity type may be the P-type.

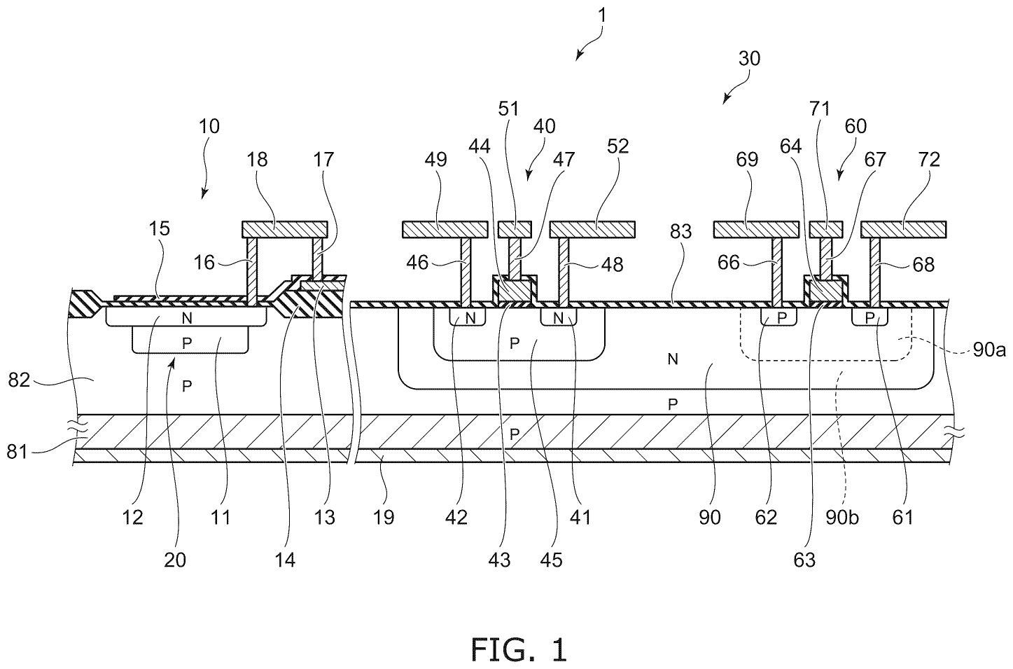

FIG. 1 is a schematic cross-sectional view of a semiconductor device 1 of the embodiment.

The semiconductor device 1 includes an optical detection portion 10 and a circuit portion 30. The optical detection portion 10 and the circuit portion 30 are provided together on a same substrate 81.

The optical detection portion 10 includes the P-type substrate 81, a P-type semiconductor layer 82 provided on the substrate 81, a back electrode 19 provided on a back surface of the substrate 81, a P-type layer 11 provided in the semiconductor layer 82, an N-type layer 12 provided on the P-type layer 11 and is in contact with the P-type layer 11, and a surface electrode 18 electrically connected to the N-type layer 12.

The substrate 81 is a silicon substrate. The semiconductor layer 82, the P-type layer 11, and the N-type layer 12 are silicon layers. The semiconductor layer 82 is epitaxially grown on the substrate 81. The P-type impurity concentration of the semiconductor layer 82 is lower than the P-type impurity concentration of the substrate 81. For example, the P-type impurity concentration of the substrate 81 is 1×10¹⁸/cm³, and the P-type impurity concentration of the semiconductor layer 82 is 1×10¹⁵/cm³ to 1×10¹⁶/cm³.

The P-type impurity concentration of the P-type layer 11 is higher than the P-type impurity concentration of the semiconductor layer 82. The P-type layer 11 and the N-type layer 12 form a P-N junction, and configure a photodiode.

For example, an insulating film 14 having a local oxidation of silicon (LOCOS) structure is provided on the surface of the semiconductor layer 82 and the surface of the N-type layer 12 of the optical detection portion 10. A trench structure may be provided herein.

The optical detection portion 10 includes a quench resistor 13 electrically connected to the N-type layer 12. The material of the quench resistor 13 is, for example, polysilicon. The quench resistor 13 is provided on the insulating film 14. An insulating protective film 15 is provided on the insulating film 14 to cover the quench resistor 13.

The N-type layer 12 is electrically connected to the surface electrode 18 via a conductive member 16. The conductive member 16 is below the surface electrode 18, penetrates the protective film 15 and the insulating film 14, and reaches the N-type layer 12.

The quench resistor 13 is electrically connected to the surface electrode 18 via a conductive member 17. The conductive member 17 is below the surface electrode 18, penetrates the protective film 15, and reaches the quench resistor 13.

The optical detection portion 10 receives light incident from the surface side of the N-type layer 12, and converts the received light into an electric signal. The optical detection portion 10 has a vertical photodiode structure in which the current flows in a direction connecting the surface electrode 18 and the back electrode 19 (vertical direction).

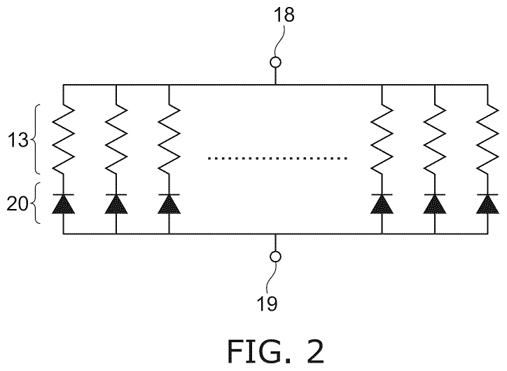

FIG. 2 is an equivalent circuit diagram of the optical detection portion 10.

The optical detection portion 10 is a silicon photomultiplier (SiPM) including multiple avalanche photodiodes 20 connected in parallel between the surface electrode 18 and the back electrode 19. The P-type layer 11 is an anode layer of the avalanche photodiode 20, and the N-type layer 12 is a cathode layer of the avalanche photodiode 20.

A reverse voltage higher than a yield voltage of the avalanche photodiode 20 is applied between the surface electrode 18 and the back electrode 19. In the SiPM, photons can be detected in a region called the Geiger mode (a region where the magnification of a photocurrent is high and proportional to an operating voltage). The Geiger mode characteristics (tilt, and the like) can be adjusted by the quench resistor 13.

The circuit portion 30 processes an electric signal output by the optical detection portion 10. The circuit portion 30 includes, for example, a complementary metal-oxide-semiconductor (CMOS) circuit. The CMOS circuit includes an N-type metal-oxide-semiconductor field effect transistor (MOSFET) 40 and a P-type MOSFET 60.

As shown in FIG. 1, an N-type first well 90 is provided in the semiconductor layer 82 of the circuit portion 30. Each semiconductor layer that configures the CMOS circuit is provided in the first well 90. Each semiconductor layer that configures the first well 90 and the CMOS circuit is a silicon layer. The first well 90 is deeper than the P-type layer 11 of the optical detection portion 10, and the depth of the first well 90 is, for example, about 3 μm to 5 μm. The polarity (conductivity type) of the first well 90 needs to be an opposite polarity (conductivity type) of the substrate 81. For example, if the substrate 81 is the N-type, the first well 90 is preferably the P-type.

The N-type MOSFET 40 includes a P-type second well 45 provided in the first well 90, an N-type first drain layer 41 provided in the second well 45, an N-type first source layer 42 provided in the second well 45, a first gate insulating film 43, and a first gate electrode 44 provided on the first gate insulating film 43.

The first drain layer 41 and the first source layer 42 are separated from each other in the second well 45. The first gate insulating film 43 is provided on the surface of the second well 45 between the first drain layer 41 and the first source layer 42.

The P-type MOSFET 60 includes a P-type second drain layer 61 provided in the first well 90, a P-type second source layer 62 provided in the first well 90, a second gate insulating film 63, and a second gate electrode 64 provided on the second gate insulating film 63.

The second drain layer 61 and the second source layer 62 are separated from each other in the first well 90. The second gate insulating film 63 is provided on the surface of the first well 90 between the second drain layer 61 and the second source layer 62.

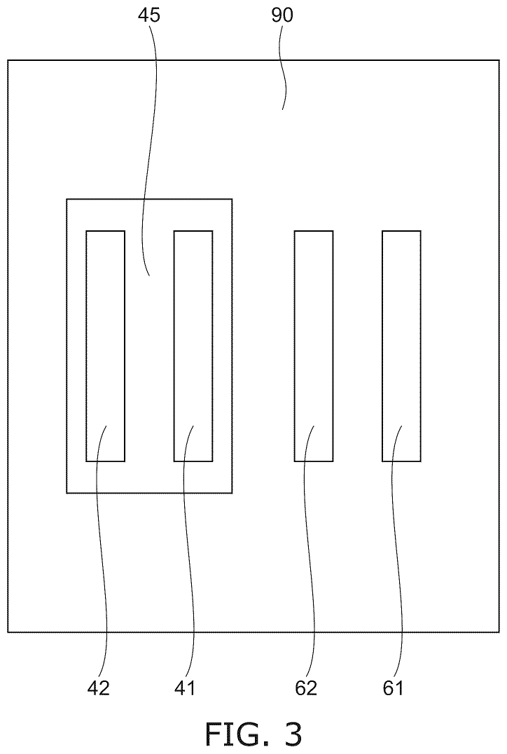

FIG. 3 is a schematic plan view of the first well 90, the second well 45, the first drain layer 41, the first source layer 42, the second drain layer 61, and the second source layer 62 in the circuit portion 30.

In the plan view shown in FIG. 3, the first well 90 surrounds the second well 45, the first drain layer 41, the first source layer 42, the second drain layer 61, and the second source layer 62.

The insulating film 83 covers the surface of each semiconductor layer (the first well 90, the second well 45, the first drain layer 41, the first source layer 42, the second drain layer 61, and the second source layer 62) of the circuit portion 30. An insulating film 83 covers the first gate electrode 44 and the second gate electrode 64.

The first drain layer 41 is electrically connected to a first drain electrode 52 via a conductive member 48. The conductive member 48 is below the first drain electrode 52, penetrates the insulating film 83, and reaches the first drain layer 41.

The first source layer 42 is electrically connected to a first source electrode 49 via a conductive member 46. The conductive member 46 is below the first source electrode 49, penetrates the insulating film 83, and reaches the first source layer 42.

The first gate electrode 44 is electrically connected to a first gate interconnection 51 via a conductive member 47. The conductive member 47 is below the first gate interconnection 51, penetrates the insulating film 83, and reaches the first gate electrode 44.

The second drain layer 61 is electrically connected to a second drain electrode 72 via a conductive member 68. The conductive member 68 is below the second drain electrode 72, penetrates the insulating film 83, and reaches the second drain layer 61.

The second source layer 62 is electrically connected to a second source electrode 69 via a conductive member 66. The conductive member 66 is below the second source electrode 69, penetrates the insulating film 83, and reaches the second source layer 62.

The second gate electrode 64 is electrically connected to a second gate interconnection 71 via a conductive member 67. The conductive member 67 is below the second gate interconnection 71, penetrates the insulating film 83, and reaches the second gate electrode 64.

The optical detection portion 10 has a vertical type structure including electrodes on the surface of the semiconductor layer 82 and the back surface of the substrate 81, respectively. Such a vertical type structure can have a wider light receiving area than a horizontal structure in which both electrodes of an anode and a cathode are disposed on the surface side of the semiconductor layer 82, and thus the sensitivity can be improved.

The potential of the back electrode 19 is applied to the substrate 81. The substrate 81 is provided also in the region of the circuit portion 30. The circuit portion 30 has a horizontal structure in which electrodes of a drain, a source, and a gate are provided on the surface side of the semiconductor layer 82. Therefore, it is required to electrically separate the substrate 81 and the circuit portion 30.

According to the embodiment, the substrate 81 and the circuit portion 30 are electrically separated by the first well 90 provided in the semiconductor layer 82 of the circuit portion 30. By applying a potential higher than that applied to the substrate 81 (the potential of the back electrode 19) to the first well 90, a depletion layer can be extended from the P-N junction of the semiconductor layer 82 and the first well 90.

Therefore, according to the embodiment, while preventing the reduction of the light receiving area of the optical detection portion 10, the optical detection portion 10 and the circuit portion 30 can be provided together on the substrate 81.

The first well 90 includes an upper region 90a that is in contact with the second drain layer 61 and the second source layer 62 of the P-type MOSFET 60, and a lower region 90b positioned between the semiconductor layer 82 and the upper region 90a.

The channel of the P-type MOSFET 60 is formed in the region between the second drain layer 61 and the second source layer 62 in the upper region 90a. The N-type impurity concentration of the upper region 90a including the region where the channel is formed is set by a threshold value of the P-type MOSFET 60. The upper region 90a functions as an N-type well of the P-type MOSFET 60.

The N-type impurity concentration of the lower region 90b is favorably lower than the N-type impurity concentration of the upper region 90a in view of securing the breakdown voltage by causing the depletion layer to be easily extended from the P-N junction between the semiconductor layer 82 and the first well 90.

The avalanche photodiode 20 is not limited to silicon and may be formed of a compound semiconductor.

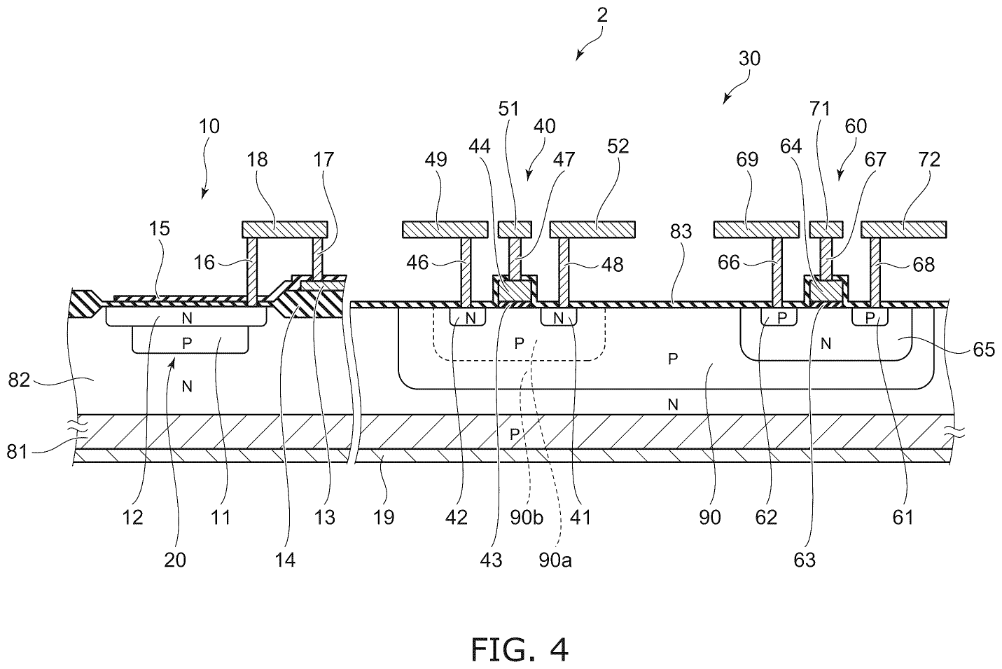

FIG. 4 is a schematic cross-sectional view of a semiconductor device 2 of another embodiment.

In the semiconductor device 2 of another embodiment, the semiconductor layer 82 is the N-type, and the first well 90 is the P-type. The P-type MOSFET 60 includes an N-type second well 65 provided in the first well 90. The second drain layer 61 and the second source layer 62 of the P-type MOSFET 60 are separated from each other in the second well 65. The first drain layer 41 and the first source layer 42 of the N-type MOSFET 40 are separated from each other in the upper region 90a of the first well 90. The upper region 90a is in contact with the first drain layer 41 and the first source layer 42 of the N-type MOSFET 40. A lower region 90b of the first well 90 is positioned between the semiconductor layer 82 and the upper region 90a.

The channel of the N-type MOSFET 40 is formed in the region between the first drain layer 41 and the first source layer 42 in the upper region 90a. The P-type impurity concentration of the upper region 90a including the region where the channel is formed is set by a threshold value of the N-type MOSFET 40. The upper region 90a functions as a P-type well of the N-type MOSFET 40.

The P-type impurity concentration of the lower region 90b is favorably lower than the P-type impurity concentration of the upper region 90a in view of securing the breakdown voltage by causing the depletion layer to be easily extend from the P-N junction between the semiconductor layer 82 and the first well 90.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1-10. (canceled)

11. A semiconductor device, comprising:
an optical detection portion; and
a circuit portion processing an electric signal output by the optical detection portion,
the optical detection portion including
a substrate of a first conductivity type,
a semiconductor layer of a second conductivity type provided on the substrate,
a back electrode provided on a back surface of the substrate,
a first conductivity-type layer provided in the semiconductor layer,
a second conductivity-type layer provided on the first conductivity-type layer and in contact with the first conductivity-type layer, and
a surface electrode electrically connected to the second conductivity-type layer,
the circuit portion including
a first well of a first conductivity type provided in the semiconductor layer,
a second well of the second conductivity type provided in the first well,
a first drain layer of the second conductivity type provided in the first well,
a first source layer of the second conductivity type provided in the first well,
a first gate insulating film provided on a surface of the first well between the first drain layer and the first source layer,
a first gate electrode provided on the first gate insulating film,
a second drain layer of the first conductivity type provided in the second well,
a second source layer of the first conductivity type provided in the second well,
a second gate insulating film provided on a surface of the second well between the second drain layer and the second source layer, and
a second gate electrode provided on the second gate insulating film.

12. The device according to claim 11, wherein
the first well includes an upper region in contact with the first drain layer and the first source layer, and a lower region positioned between the semiconductor layer and the upper region, and
a first conductivity-type impurity concentration of the lower region is lower than a first conductivity-type impurity concentration of the upper region.

13. The device according to claim 11, wherein
the optical detection portion further includes a quench resistor electrically connected to the second conductivity-type layer.

14. The device according to claim 13, wherein
the quench resistor includes polysilicon.

15. The device according to claim 11, wherein
the first conductivity type is a p-type, the second conductivity type is an n-type,
the first conductivity-type layer is an anode layer, and the second conductivity-type layer is a cathode layer.

16. The device according to claim 11, wherein
the optical detection portion is a silicon photomultiplier (SiPM) including a plurality of avalanche photodiodes connected in parallel between the surface electrode and the back electrode.

17. The device according to claim 11, wherein
the optical detection portion has a vertical photodiode structure in which a current flows in a direction of connecting the surface electrode and the back electrode.

18. The device according to claim 11, wherein
a depth of the first well is deeper than a depth of the first conductivity-type layer of the optical detection portion.
